(19) United States
(12) Patent Application Publication
(10) Pub. No.: US 2017/0077913 A1
(43) Pub. Date: Mar. 16, 2017

(54) PULSE WIDTH MODULATION CIRCUIT

(71) Applicant: Shenzhen China Star Optoelectronics Technology Co., Ltd., Shenzhen, Guangdong (CN)

(72) Inventor: Xianming ZHANG, Shenzhen, Guangdong (CN)

(73) Assignee: Shenzhen China Star Optoelectronics Technology Co., Ltd., Shenzhen, Guangdong (CN)

(21) Appl. No.: 14/901,309

(22) PCT Filed: Oct. 31, 2015
(86) PCT No.: PCT/CN2015/093494

§ 371 Date: Dec. 28, 2015

(30) Foreign Application Priority Data
Sep. 11, 2015 (CN) 201510579794.6

(51) Int. Cl. H03K 5/04

(52) U.S. Cl. CPC H03K 5/04

(57) ABSTRACT

The present invention discloses a pulse width modulation circuit, comprising: an input circuit, inputting a voltage through an input end; a voltage difference calculation circuit, and the voltage difference calculation circuit comprises a resistor and a subtracter, and one end of the resistor is coupled to an output end of the input circuit, and the other end is employed to be an output end of the pulse width modulation circuit, and two input ends of the subtracter are respectively coupled to the two ends of the resistor; an analog dimming circuit, and an input end thereof is coupled to an output end of the subtracter, and an output end thereof is coupled to a control end of the input circuit to receive the voltage difference and convert the voltage difference into a pulse width modulation signal to be outputted to the inputted circuit for current feedback.

### CROSS REFERENCE

This application claims the priority of Chinese Patent Application No. 201510579794.6, entitled “Pulse width modulation circuit”, filed on Sep. 11, 2015, the disclosure of which is incorporated herein by reference in its entirety.

### FIELD OF THE INVENTION

The present invention relates to a circuit field, and more particularly to a pulse width modulation circuit.

### BACKGROUND OF THE INVENTION

The main function of Pulse Width Modulation (PWM) circuit is to convert the amplitude of the input voltages into pulses with certain widths, and widely applied in many aspects of measurement, communication and power control and conversion.

At present, most of the PWM Integrated Circuits (IC) employs voltage feedback for performing modulation. However, as utilizing the voltage feedback to perform modulation, due to the small loading of the PWM IC or the large loading variation of the PWM IC, the PWM IC enters the Discontinous Conduction Mode and the range of the voltage variation is large and the circuit becomes unstable.

### SUMMARY OF THE INVENTION

The embodiment of the present invention provides a pulse width modulation circuit, which can perform current feedback to the pulse width modulation circuit for ensuring the working voltage stability.

The embodiment of the present invention provides a pulse width modulation circuit, comprises:

an input circuit, inputting a voltage through an input end;

a voltage difference calculation circuit, and the voltage difference calculation circuit comprises a resistor and a subtracter, and one end of the resistor is coupled to an output end of the input circuit, and the other end is employed to be an output end of the pulse width modulation circuit, and two input ends of the subtracter are respectively coupled to the two ends of the resistor, and is employed to calculate a voltage difference of the two ends of the resistor, and the voltage difference is employed to reflect a current volume of the output end;

an analog dimming circuit, and an input end of the analog dimming circuit is coupled to an output end of the subtracter, and an output end of the analog dimming circuit is coupled to a control end of the input circuit, and is employed to receive the voltage difference outputted by the voltage difference calculation circuit and convert the voltage difference into a pulse width modulation signal to be outputted to the inputted circuit for current feedback.

The input circuit comprises:

a field effect transistor and an inductor;

a gate of the field effect transistor is coupled to the analog dimming circuit, and a drain of the field effect transistor is coupled to one end of the inductor, and a source of the field effect transistor is grounded, and the other end of the inductor is coupled to an input voltage.

The input circuit further comprises a diode, and a positive electrode of the diode is coupled to the input circuit, and a negative electrode of the diode is coupled to the voltage difference calculation circuit, and is employed to maintain an output current direction of the input circuit.

The output circuit further comprises a first capacitor, and one end of the first capacitor is coupled to the negative electrode of the diode and a common connection point of the voltage difference calculation circuit, and the other end of the capacitor is grounded, and is employed to maintain voltage stability of the output circuit.

The analog dimming circuit further comprises a second capacitor, and one end of the second capacitor is coupled to a common connection point of the analog dimming circuit and the subtracter, and the other end of the second capacitor is grounded, and is employed to maintain voltage stability of the output circuit.

The first capacitor is a ceramic capacitor or a tantalum capacitor.

The second capacitor is a ceramic capacitor or a tantalum capacitor.

The resistor is a power resistor.

In the pulse width modulation circuit of the present invention, the voltage difference of the two ends of the resistor at the output end of the PWM circuit is measured, and thus, what the voltage difference reflects is the current of the output end of the PWM circuit. Then, the voltage difference is converted into a pulse width modulation to be outputted to the inputted circuit for achieving current feedback. Accordingly, the circuit works in the continuous current mode to ensure the PWM working voltage stability.

### BRIEF DESCRIPTION OF THE DRAWINGS

FIG. 1 is a structure diagram of the first embodiment of a pulse width modulation circuit provided by the embodiment of the present invention;

FIG. 2 is a structure diagram of the second embodiment of a pulse width modulation circuit provided by the embodiment of the present invention;

FIG. 3 is a structure diagram of the third embodiment of a pulse width modulation circuit provided by the embodiment of the present invention.

### DETAILED DESCRIPTION OF PREFERRED EMBODIMENTS

The embodiment of the present invention provides a pulse width modulation circuit, which can perform current feedback to the pulse width modulation circuit for ensuring the working voltage stability.

In order to enable persons skilled in the art to better understand the technical solution of the present invention, embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should all be considered within the scope of protection of the present invention.

The terminologies “first”, “second” and “third” in the specification, claims and aforesaid figures of the present invention are used for distinguishing different objects but not for describing the specific sequence. Furthermore, the terms “including” and its any deformations are intended to cover non-exclusive inclusion. For example, a process, a method, a system, a product or a device comprising a series of steps or units which is not limited to the steps or units already listed, but optionally further comprises steps or units which are not listed, or optionally further comprises other steps or units which are inherent in these the process, the method, the product or the device.

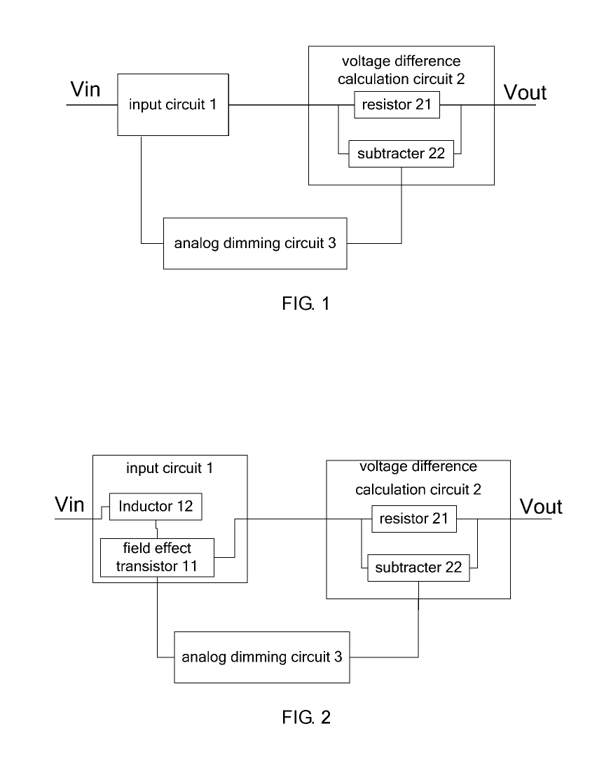

First, refer to FIG. 1. FIG. 1 is a structure diagram of the first embodiment of a pulse width modulation circuit provided by the embodiment of the present invention. As shown in FIG. 1, the pulse width modulation circuit provided by the first embodiment of the present invention comprises:

an input circuit 1, inputting a voltage through an input end.

a voltage difference calculation circuit 2, and the voltage difference calculation circuit 2 comprises a resistor 21 and a subtracter 12, and one end of the resistor 21 is coupled to an output end of the input circuit 1, and the other end is employed to be an output end of the pulse width modulation circuit, and two input ends of the subtracter 12 are respectively coupled to the two ends of the resistor 21, and is employed to calculate a voltage difference of the two ends of the resistor 21, and the voltage difference is employed to reflect a current volume of the output end.

an analog dimming circuit 3, and an input end of the analog dimming circuit 3 is coupled to an output end of the subtracter 12, and an output end of the analog dimming circuit 3 is coupled to a control end of the input circuit 1, and is employed to receive the voltage difference outputted by the voltage difference calculation circuit 2 and convert the voltage difference into a pulse width modulation signal to be outputted to the inputted circuit 1 for current feedback.

Specifically, in the embodiment of the present invention, as the analog dimming circuit 3 converts the voltage difference outputted by the voltage difference calculation circuit 2 into the PWM signal, the voltage difference of the input end of the analog dimming circuit 3 is proportional to the duty ratio of the PWM signal. When the voltage difference is larger, the duty ratio of the PWM signal is larger, and the ratio of outputting high voltage level is larger; when the voltage difference is smaller, the duty ratio of the PWM signal is smaller, and the ratio of outputting high voltage level is smaller.

In the first embodiment of the present invention, after the input end of the input circuit 1 is inputted with voltages, the pulse width modulation circuit starts to work. The subtracter 12 of the voltage difference calculation circuit 2 measures the voltages of the two ends of the resistor 21, and subtracts the voltages of the two ends of the resistor 21 to obtain the voltage difference of the two ends of the resistor 21. Thus, the voltage difference can reflect a current flowing through the resistor 21. The current is also the output current of the PWM circuit. Then, by inputting the voltage difference into the analog dimming circuit 3, and the analog dimming circuit 3 converts the voltage difference into a pulse width modulation signal. The pulse width modulation signal is inputted into the control end of the input circuit 1 to control the input circuit 1 for achieving the current feedback to the pulse width modulation circuit. Accordingly, the circuit works in the continuous current mode to ensure that the variation of the PWM working voltage is small.

The present invention measures the voltage difference of the two ends of the resistor at the output end of the PWM circuit, and thus, what the voltage difference reflects is the current of the output end of the PWM circuit. Then, the voltage difference is converted into a pulse width modulation to be outputted to the inputted circuit for achieving current feedback. Accordingly, the circuit works in the continuous current mode to ensure that the variation of the PWM working voltage is small.

As referring to FIG. 2, FIG. 2 is a structure diagram of the second embodiment of a pulse width modulation circuit provided by the embodiment of the present invention. As shown in FIG. 2, FIG. 2 is the specific description to the pulse width modulation circuit shown in FIG. 1. In FIG. 2:

The input circuit 1 can comprises a field effect transistor 11 and an inductor 12. A gate of the field effect transistor 11 is coupled to the analog dimming circuit 3, and a drain of the field effect transistor 11 is coupled to one end of the inductor 12, and a source of the field effect transistor 11 is grounded, and the other end of the inductor 12 is coupled to an input voltage.

Specifically, the gate of the field effect transistor 11 is the control end of the input circuit 1. The PWM signal outputted by the analog dimming circuit 3 is inputted to the gate of the field effect transistor 11. Accordingly, the PWM signal and the field effect transistor 11 are employed together to control the input circuit 1.

Specifically, after the analog dimming circuit 3 outputs the PWM signal, the PWM signal is inputted into the input circuit 1 through the gate of the field effect transistor 11. When the PWM signal is at high voltage level, the field effect transistor 11 is activated, and the inductor 12 is grounded, and the input circuit 1 and the output circuit 2 are disconnected; when the PWM signal is at low voltage level, the field effect transistor is deactivated, and the input circuit 1 and the output circuit 2 are connected. With such arrangement, it realizes that the PWM signal is employed to control the input circuit 1. The PWM signal is obtained by converting the voltage difference of the resistor in the output circuit 2. Therefore, the current feedback to the pulse width modulation circuit is achieved.

The input circuit 1 further comprises a diode 13, and a positive electrode of the diode 13 is coupled to the input circuit 1, and a negative electrode of the diode 13 is coupled to the voltage difference calculation circuit 2, and is employed to maintain an output current direction of the input circuit 1.

In the embodiment of the present invention, due to the single way conduction of the diode, with adding one diode 13 at the output end of the input circuit 1, the current direction of the input circuit is from the positive electrode of the diode 13 to the negative electrode of the diode 13. Conversely, it cannot be conducted.

Preferably, in some embodiments of the present invention, the output circuit 2 further comprises a first capacitor 21, and one end of the first capacitor 21 is coupled to the negative electrode of the diode 13 and a common connection point of the voltage difference calculation circuit 2, and the other end of the capacitor 21 is grounded, and is employed to maintain voltage stability of the output circuit 2.

Preferably, in some embodiments of the present invention, the analog dimming circuit 3 further comprises a second capacitor 31, and one end of the second capacitor 31 is coupled to a common connection point of the analog dimming circuit 3 and the subtracter 12, and the other end of the second capacitor 31 is grounded, and is employed to maintain voltage stability of the output circuit 2.

Preferably, in some embodiments of the present invention, the first capacitor 21 is a ceramic capacitor or a tantalum capacitor.

Preferably, in some embodiments of the present invention, the second capacitor 31 is a ceramic capacitor or a tantalum capacitor.

Preferably, in some embodiments of the present invention, the resistor is a power resistor.

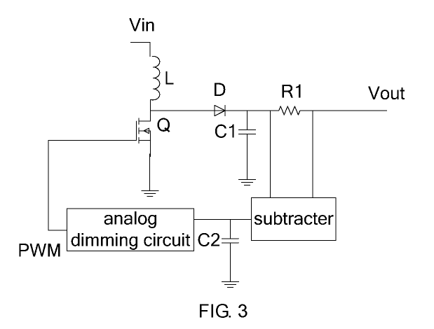

As referring to FIG. 3, and FIG. 3 is a structure diagram of the third embodiment of a pulse width modulation circuit provided by the embodiment of the present invention.

As shown in FIG. 3, the pulse width modulation circuit comprises the pulse width modulation circuit comprises an input circuit 1, a voltage difference calculation circuit 2 and an analog dimming circuit 3. The input circuit 1 comprises an inductor L, a field effect transistor Q and a diode D. The voltage difference calculation circuit 2 comprises a first capacitor C1 and a subtracter. The analog dimming circuit 3 comprises an analog dimming circuit and a second capacitor C2. The field effect transistor Q is an enhancement mode NMOS transistor.

In the input circuit 1, one end of the inductor L is coupled to the drain of the field effect transistor Q, and the positive electrode of the diode D is coupled to the common connection point of the inductor L and the drain of the field effect transistor Q, and the gate of the field effect transistor Q is coupled to the output end of the analog dimming circuit, and the source of the field effect transistor Q is grounded; wherein one end of the inductor L is employed to be the input end Vin of the circuit, and the gate of the field effect transistor Q is employed to be the control end of the input circuit 1, and by controlling whether the field effect transistor Q is activated or not to control the current direction of the input circuit 1 and thus, to control the entire pulse width modulation circuit.

In the voltage difference calculation circuit 2, one end of the resistor R is coupled to the negative electrode of the diode D, and the other end of the resistor is employed to be the output end Vout of the pulse width modulation circuit for outputting voltages, and two input ends of the subtracter are coupled to the two ends of the resistor R, and one end of the first capacitor C1 is coupled to negative electrode of the diode D and the common end of the resistor R, and the other end of the first capacitor C1 is grounded; wherein the subtracter is employed to calculate the voltage difference of the two ends of the resistor R, and thus, the voltage difference can reflect the current flowing through the resistor R.

In the analog dimming circuit 3, the output end of the subtracter is coupled to the input end of the analog dimming circuit 3, and the common connection point is grounded through the second capacitor C2, and the analog dimming circuit 3 converts the voltage difference outputted from the output end of the subtracter into the PWM signal to be outputted to the control end of the input circuit, i.e. the gate of the field effect transistor Q, and thus to control the input circuit 1.

Preferably, the first capacitor C1 is a ceramic capacitor or a tantalum capacitor.

Preferably, the second capacitor C2 is a ceramic capacitor or a tantalum capacitor.

Preferably, the resistor R is a power resistor.

Specifically, after the input end of the input circuit 1 is inputted with voltages, the circuit starts to work. When the diode D is conducted, and the current is larger, the current flowing through the resistor R is larger, and then, the voltage difference of the resistor R received by the subtracter is larger. Because the voltage difference of the input end of the analog dimming circuit 3 is proportional to the duty ratio of the PWM signal, the ratio of high voltage level is larger after the analog dimming circuit 3 converts the voltage difference into the PWM signal. When the PWM outputs high voltage level, the field effect transistor Q is conducted, and the input circuit 1 is grounded through the inductor L, and then the current of the resistor R is decreased; after the current of the resistor R is decreased, the voltage difference of the resistor R received by the subtracter is smaller. Then, the ratio of high voltage level is smaller after the analog dimming circuit 3 converts the voltage difference into the PWM signal. Accordingly, the conducting period of the field effect transistor Q becomes shorter, and the period that the current of the input circuit 1 flows from the diode D to the resistor 11 of the output circuit becomes longer. It results in that the current of the resistor R becomes larger to maintain the current stability of the resistor R to make the current function in a continuous current mode to ensure the voltage stability of the circuit.

It is understandable in practical to the person who is skilled in the art that all or portion of the processes in the method according to the aforesaid embodiment can be accomplished with the computer program to instruct the related hardwares. The program can be stored in a readable storage medium if the computer. As the program is executed, the processes of the embodiments in the aforesaid respective methods can be included. The storage medium can be a hardisk, an optical disc, a Read-Only Memory (ROM) or a Random Access Memory (RAM).

Above are embodiments of the present invention, which does not limit the scope of the present invention. Any modifications, equivalent replacements or improvements within the spirit and principles of the embodiment described above should be covered by the protected scope of the invention.

What is claimed is:

1. A pulse width modulation circuit, wherein the circuit comprises:
an input circuit, inputting a voltage through an input end;
a voltage difference calculation circuit, and the voltage difference calculation circuit comprises a resistor and a subtracter, and one end of the resistor is coupled to an output end of the input circuit, and the other end is employed to be an output end of the pulse width modulation circuit, and two input ends of the subtracter are respectively coupled to the two ends of the resistor, and is employed to calculate a voltage difference of the two ends of the resistor, and the voltage difference is employed to reflect a current volume of the output end;
an analog dimming circuit, and an input end of the analog dimming circuit is coupled to an output end of the subtracter, and an output end of the analog dimming circuit is coupled to a control end of the input circuit, and is employed to receive the voltage difference outputted by the voltage difference calculation circuit and convert the voltage difference into a pulse width modulation signal to be outputted to the inputted circuit for current feedback.

2. The pulse width modulation circuit according to claim 1, wherein the input circuit comprises:
a field effect transistor and an inductor;
a gate of the field effect transistor is coupled to the analog dimming circuit, and a drain of the field effect transistor is coupled to one end of the inductor, and a source of the field effect transistor is grounded, and the other end of the inductor is coupled to an input voltage.

3. The pulse width modulation circuit according to claim 1, wherein the input circuit further comprises a diode, and a positive electrode of the diode is coupled to the input circuit, and a negative electrode of the diode is coupled to the voltage difference calculation circuit, and is employed to maintain an output current direction of the input circuit.

4. The pulse width modulation circuit according to claim 2, wherein the input circuit further comprises a diode, and a positive electrode of the diode is coupled to the input circuit, and a negative electrode of the diode is coupled to the voltage difference calculation circuit, and is employed to maintain an output current direction of the input circuit.

5. The pulse width modulation circuit according to claim 3, wherein an output circuit further comprises a first capacitor, and one end of the first capacitor is coupled to the negative electrode of the diode and a common connection point of the voltage difference calculation circuit, and the other end of the capacitor is grounded, and is employed to maintain voltage stability of the output circuit.

6. The pulse width modulation circuit according to claim 4, wherein an output circuit further comprises a first capacitor, and one end of the first capacitor is coupled to the negative electrode of the diode and a common connection point of the voltage difference calculation circuit, and the other end of the capacitor is grounded, and is employed to maintain voltage stability of the output circuit.

7. The pulse width modulation circuit according to claim 5, wherein the analog dimming circuit further comprises a second capacitor, and one end of the second capacitor is coupled to a common connection point of the analog dimming circuit and the subtracter, and the other end of the second capacitor is grounded, and is employed to maintain voltage stability of the output circuit.

8. The pulse width modulation circuit according to claim 6, wherein the analog dimming circuit further comprises a second capacitor, and one end of the second capacitor is coupled to a common connection point of the analog dimming circuit and the subtracter, and the other end of the second capacitor is grounded, and is employed to maintain voltage stability of the output circuit.

9. The pulse width modulation circuit according to claim 5, wherein the first capacitor is a ceramic capacitor or a tantalum capacitor.

10. The pulse width modulation circuit according to claim 6, wherein the first capacitor is a ceramic capacitor or a tantalum capacitor.

11. The pulse width modulation circuit according to claim 7, wherein the second capacitor is a ceramic capacitor or a tantalum capacitor.

12. The pulse width modulation circuit according to claim 8, wherein the second capacitor is a ceramic capacitor or a tantalum capacitor.

13. The pulse width modulation circuit according to claim 7, wherein the resistor is a power resistor.

14. The pulse width modulation circuit according to claim 8, wherein the resistor is a power resistor.
